(19) United States
(12) Patent Application Publication
(10) Pub. No.: US 2022/0063247 A1
(43) Pub. Date: Mar. 3, 2022

(54) COMPOSITE SUBSTRATE AND MANUFACTURING METHOD THEREOF

(71) Applicant: AZOTEK CO., LTD., Taoyuan City (TW)

(72) Inventor: Hung-Jung LEE, Taoyuan City (TW)

(21) Appl. No.: 17/211,850

(22) Filed: Mar. 25, 2021

(30) Foreign Application Priority Data
Sep. 1, 2020 (TW) 109129949

(51) Int. Cl. B32B 15/08; B32B 15/18; B32B 27/28; B32B 7/12; B32B 7/025

(52) U.S. Cl. CPC B32B 15/08; B32B 15/18; B32B 27/281; B32B 2307/304; B32B 7/025; B32B 2457/08; B32B 2307/202; B32B 7/12

(57) ABSTRACT

The present disclosure is related to a composite substrate, including a first metal base material, a first bonding layer, and a second metal base material. The first metal base material includes a first metal layer and a first insulating layer, and the first insulating layer is disposed on the first metal layer. The first bonding layer, disposed on the first insulating layer, in which a dielectric constant of the first bonding layer is lower than 3 and a dissipation factor of the first bonding layer is lower than 0.005. The second metal base material includes a second metal layer and a second insulating layer; the second insulating layer is disposed on the first bonding layer, and the second metal layer is disposed on the second insulating layer. A method of manufacturing a composite substrate is further provided in the present disclosure.

### CROSS-REFERENCE TO RELATED APPLICATION

This application claims priority to Taiwan Application Serial Number 109129949, filed Sep. 1, 2020, which is herein incorporated by reference in its entirety.

### BACKGROUND

### Field of Invention

The present disclosure is directed to a composite substrate and manufacture method thereof. In particular, the present disclosure is directed to the manufacture method of the composite substrate that can flexibly adjust the thickness of each layer and adhesion of each layer at the lower temperature.

### Description of Related Art

Printed circuit boards are indispensable materials in electronic products, and as the demand for consumer electronic products grows, the demand for printed circuit boards also increases with days. Because flexible printed circuit boards have the characteristics of flexibility, three-dimensional wiring and the like, they are currently widely used in computers, communication products and consumer electronic products under the development tendency of scientific electronic products that emphasize lightness, thinness, shortness and flexibility.

In view of the increasing specification requirements of current electronic products nowadays, high-frequency circuits and circuit boards that can be diversified and adjusted have become increasingly important. Therefore, it is necessary to provide a manufacture method of a composite substrate that reduces delay of resistance capacity, reduces signal attenuation and improves the thickness flexibility of interlayer configuration and yield.

### SUMMARY

One aspect of the present disclosure provides a composite board, including a first metal base material, first bonding layer and a second metal base material. The first metal base material includes a first metal layer and a first insulating layer, in which the first insulating layer includes a first surface and a second surface of opposite to the first surface. The first surface of the first insulating layer faces down and is disposed on the first metal layer. The first bonding layer is disposed on the second surface of the first insulating layer, in which a dielectric constant of the first bonding layer is lower than 3, and a dissipation factor of the first bonding layer is lower than 0.005. The second metal base material includes a second metal layer and a second insulating layer, in which the second insulating layer includes a third surface and a fourth surface opposite to the third surface, in which the third surface of the second insulating layer faces down and is disposed on the first bonding layer, in which the second metal layer is disposed on the fourth surface of the second insulating layer.

In some embodiments, a material of the first metal layer and the second metal layer includes Cu, Al, Au, Ag, Sn, Pb, Sn—Pb alloy, Fe, Pd, Ni, Cr, Mo, W, Zn, Mn, Co, stainless steel, or a combination thereof.

In some embodiments, at least one of the first metal layer and the second metal layer is a patterned metal layer.

In some embodiments, a surface of the patterned metal layer includes a circuit structure.

In some embodiments, a material of the first insulating layer and the second insulating layer includes Polyimide, Polyethylene Terephthalate, Teflon, Liquid Crystal Polymer, Polyethylene, Polypropylene, Polystyrene, Polyvinyl Chloride, Nylon, Acrylic, Acrylonitrile-Butadiene-Styrene, Phenolic Resins, Epoxy, Polyester, Silicone, Polyurethane, polyamide-imide, or a combination thereof.

In some embodiments, the first insulating layer, the second insulating layer or both are a modified insulating material.

In some embodiments, the modified insulating material includes a modified polyimide, a soluble liquid crystal polymer, or a combination thereof.

In some embodiments, the soluble liquid crystal polymer includes a functional group selected from the group consisting of amino group, carboxamido group, imido group, amidino group, aminocarbonylamino group, aminothiocarbonyl group, aminocarbonyloxy group, aminosulfonyl group, aminosulfonyloxy group, aminosulfonylamino group, carboxyl ester group, (carboxyl ester)amino group, alkoxycarbonyl)oxy group, alkoxycarbonyl group, hydroxyamino group, alkoxyamino group, cyanate group and isocyanato group.

In some embodiments, a coefficient of thermal expansion of the first bonding layer is lower than 50 μm/m/° C.

In some embodiments, a coefficient of water absorption of the first bonding layer is lower than 0.5% at a temperature of 25° C. within 24 hours.

In some embodiments, a material of the first bonding layer includes polyester resin, epoxy resin, butyral phenolic resin, phenoxy resin, acrylic resin, polyurethane resin, silicone rubber resin, parylene resin, bismaleinide resin, polyimide resin, urethane resin, silicon dioxide resin, flueon resin, or a combination thereof.

In some embodiments, the composite board further includes a bonding structure located between the first bonding layer and the second metal base material, and the bonding structure includes a second bonding layer.

In some embodiments, the bonding structure further includes a plurality of third insulating layers and a plurality of second bonding layers, in which any one of the plurality of third insulating layers is laminated with any one of the plurality of second bonding layers, in which an undermost third insulating layer of the plurality of third insulating layers is disposed on the first bonding layer, and an uppermost second bonding layer of the plurality of second bonding layers is disposed beneath the second insulating layer.

Another aspect of the present disclosure provides a method of manufacturing a composite substrate, including the following steps: providing a first metal base material, including a first metal layer and a first insulating layer, in which the first insulating layer is disposed on the first metal layer; providing a second metal base material, including a second metal layer and a second insulating layer, in which the second insulating layer is disposed beneath the second metal layer; providing a first bonding layer, in which a dielectric constant of the first bonding layer is lower than 3, and a dissipation factor of the first bonding layer is lower than 0.005; disposing the first bonding layer between the first metal base material and the second metal base material to obtain a composite substrate, in which the first bonding layer is adhered to the first insulating layer and the second insulating layer.

In some embodiments, the method further includes forming a bonding structure between the first bonding layer and the second metal base material, wherein the bonding structure comprises a second bonding layer.

In some embodiments, the bonding structure further includes a plurality of third insulating layers and a plurality of second bonding layers, in which any one of the plurality of third insulating layers is laminated with any one of the plurality of second bonding layers, in which an undermost third insulating layer of the plurality of third insulating layers is disposed on the first bonding layer, and an uppermost second bonding layer of the plurality of second bonding layers is disposed beneath the second insulating layer.

In some embodiments, the step of disposing the first bonding layer between the first metal base material and the second metal base material includes heating the first bonding layer at a temperature of lower than 280° C. to adhere the first bonding layer between the first metal base material and the second metal base material.

In some embodiments, the step of heating the first bonding layer at the temperature of lower than 280° C. includes a first heating stage and a second heating stage.

In some embodiments, a temperature of the first heating stage is from 100° C. to 150° C.

In some embodiments, a temperature of the second heating stage is from 250° C. to 280° C.

### BRIEF DESCRIPTION OF THE DRAWINGS

The various aspects of the content of the present disclosure can be best understood from the following detailed description and reading together with the accompanying drawings.

FIGS. 1A to 1C schematically illustrate cross-sectional views of a process flow of manufacturing a composite substrate according to some embodiments of the present disclosure.

FIG. 2 schematically illustrates a cross-sectional view of a composite substrate according to other embodiments of the present disclosure.

FIG. 3 schematically illustrates a cross-sectional view of a composite substrate according to other embodiments of the present disclosure.

FIGS. 4A to 4D schematically illustrate cross-sectional views of a process flow of manufacturing a composite substrate according to other embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this present disclosure generally have ordinary meanings in the field and the context in which they are used. The examples used in the present disclosure, including examples of any terms discussed herein, are only illustrative and do not limit the scope and meaning of the present disclosure or any exemplary terms. Likewise, the present disclosure is not limited to some embodiments provided in the present disclosure.

It will be understood that despite the terms “first”, “second”, etc. may be used herein to describe various elements, these elements should not be limited by these terms. These terms are used to distinguish one element from another. For example, the first element may be referred to as the second element, and similarly, the second element may be referred to as the first element without departing from the scope of the embodiment.

As used herein, the term “and/or” includes any and all combinations of one or a variety of associated listed items.

As used herein, the terms “comprises” and/or “comprising”, “includes” and/or “including” or “has” and/or “having”, etc. should be understood as open type, i.e., including but not limited.

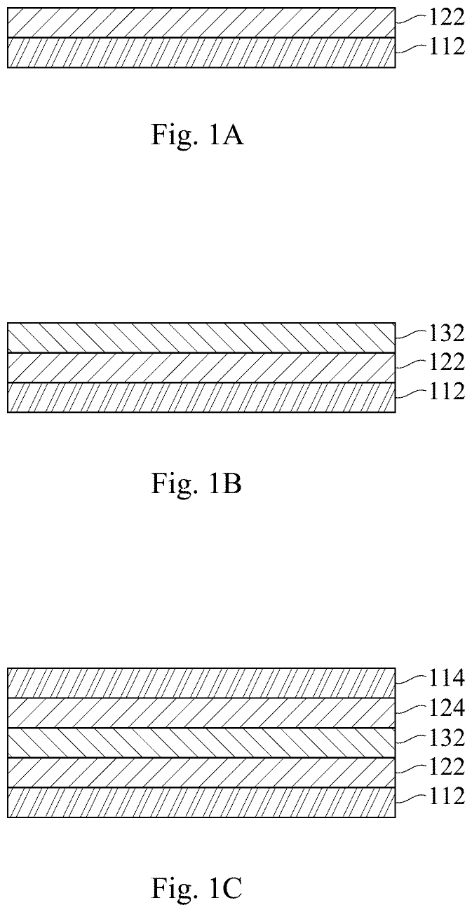

FIGS. 1A to 1C schematically illustrate cross-sectional views of a process flow of manufacturing a composite substrate according to some embodiments of the present disclosure. First, referring to FIG. 1A, a first metal base material is provided, including a first metal layer 112 and a first insulating layer 122, in which the first insulating layer 122 is disposed on the first metal layer 112.

In some embodiments, a material of the first metal layer 112 includes Cu, Al, Au, Ag, Sn, Pb, Sn—Pb alloy, Fe, Pd, Ni, Cr, Mo, W, Zn, Mn, Co, stainless steel, or a combination thereof.

In some embodiments, a material of the first insulating layer 122 includes Polyimide (PI), Polyethylene Terephthalate (PET), Teflon, Liquid Crystal Polymer (LCP), Polyethylene (PE), Polypropylene (PP), Polystyrene (PS), Polyvinyl Chloride (PVC), Nylon or Polyamides, Acrylic, Acrylonitrile-Butadiene-Styrene (ABS), Phenolic Resin, Epoxy, Polyester, Silicone, Polyurethane (PU), polyamide-imide (PAI), or a combination thereof. In one embodiment, some kinds of the insulating materials (for example, LCP) can form the first insulating layer 122 independently without the formation basis of the first metal layer 112, and the formed first insulating layer 122 can be adhered to the first metal layer 112 without the support of adhesives while heated at higher than or equal to 280° C. In one embodiment, the first insulating layer 122 is modified insulating material, such as a modified polyimide (MPI) or a soluble liquid crystal polymer. The soluble liquid crystal polymer is formed by modifying the functional groups of liquid crystal polymers. For example, the functional groups of liquid crystal polymers can be modified by addition or substitution. The soluble liquid crystal polymers after the functional group modification may have the functional groups as described below, such as amino group, carboxamido group, imido group or imino group, amidino group, aminocarbonylamino group, aminothiocarbonyl group, aminocarbonyloxy group, aminosulfonyl group, aminosulfonyloxy group, aminosulfonylamino group, carboxyl ester group, (carboxyl ester)amino group, alkoxycarbonyl)oxy group, alkoxycarbonyl group, hydroxyamino group, alkoxyamino group, cyanate group, isocyanato group or combination, but are not limited. The solubility of the soluble liquid crystal polymers is higher than liquid crystal polymers without the functional group modification in the specified solvents.

Next, please referring to FIG. 1B, a first bonding layer 132 is provided, in which a dielectric constant of the first bonding layer 132 is lower than 3, such as 1.5, 1.6, 1.7, 1.8, 1.9, 2.0, 2.1, 2.2, 2.3, 2.4 or 2.5, and a dissipation factor of the first bonding layer 132 is lower than 0.005, such as 0.0015, 0.0016, 0.0017, 0.0018, 0.0019, 0.002, 0.0021, 0.0022, 0.0023, 0.0024, 0.0025, 0.0026, 0.0027, 0.0028, 0.0029, 0.003, 0.0031, 0.0032, 0.0033, 0.0034, or 0.0035. Additionally, it is worth mentioning that a coefficient of thermal expansion and a coefficient of water absorption of the first bonding layer 132 are lower than adhesives generally used, in which the coefficient of thermal expansion of the first bonding layer 132 is at least lower than 50 μm/m/° C., and the coefficient of water absorption of the first bonding layer 132 is lower than 0.5% at a temperature of 25° C. within 24 hours. Then, the first bonding layer 132 is disposed on the first metal base material to adhere to the first insulating layer 122. In some embodiments, a material of the first bonding layer 132 includes polyester resin, epoxy resin, butyral phenolic resin, phenoxy resin, acrylic resin, polyurethane resin, silicone rubber resin, parylene resin, bismaleinide resin, polyimide resin, urethane resin, silicon dioxide resin, flueon resin, or a combination thereof.

Please continue refer to FIG. 1C, a second metal base material is provided, and the manufacture method and the materials thereof can be referred to the first metal base material, in which the second metal base material includes a second metal layer 114 and a second insulating layer 124 disposed beneath the second metal layer 114. Then, the second metal base material is disposed on the first bonding layer 132 to adhere the second insulating layer 124 to the first bonding layer 132. That is, the first bonding layer 132 is adhered to the first insulating layer 122 and the second insulating layer 124 to obtain a composite substrate (can also be referred to as double-layer board in the figure).

In some embodiments, the step of disposing the first bonding layer 132 between the first metal base material and the second metal base material includes heating the first bonding layer 132 at a temperature of lower than 280° C. to adhere the first bonding layer 132 between the first metal base material and the second metal base material. That is, the obtained composite substrate is formed by adhering the first bonding layer 132 to the first insulating layer 122 and the second insulating layer 124. In one embodiment, the step of heating the first bonding layer 132 at the temperature of lower than 280° C. includes two heating stages, in which a temperature of the first heating stage is from 100° C. to 150° C. (for example, 100° C., 110° C., 120° C., 130° C., 140° C., 150° C. or any value in the abovementioned intervals), and a temperature of the second heating stage is from 250° C. to 280° C. (for example, 250° C., 260° C., 270° C., 275° C. or any value in the abovementioned intervals).

It should be emphasized that during the conventional double-layer board manufacture process, for example, a lamination of a double-layer metal board and an insulating layer interposed between the double-layer metal board at a high temperature higher than 280° C. while the insulating layer is liquid crystal polymer by heating the insulating layer to the temperature between glass transition temperature and melting temperature to adhere to the metal board, which is caused by rearranging the molecules in the insulating layer, can often result in the adverse effects such as uneven adhesion between the insulating layer and the metal layers, poor alignment caused by flowable state, or even metal board shrinkage. In addition, the limited thickness of the insulating layer, such as a thickness of a single-layer MPI is less than 125 μm, limits the thickness of the conventional double-layer board. If the insulating layer and the metal board are adhered by general adhesives, the abovementioned adhesion efficiency that the insulating layer and the metal board are steadily adhered can hardly be achieved.

In comparison, in some embodiments of the present disclosure, the first metal base material and the second metal base material can be adhered by the first bonding layer 132 at the temperature lower than 280° C. by disposing the first bonding layer 132 between the first insulating layer 122 of the first metal base material and the second insulating layer 124 of the second metal base material, and the thickness of the double-layer board can be adjusted according to the requirements without affecting signal transmission, causing signal loss and board deformation by adjusting the layer amount or the thickness of the bonding layer, benefit from the low dielectric constant and low dielectric loss of the characteristics of the bonding layer. The known adverse effects caused by high temperature lamination can be improved, product quality can be increased, and even the thickness flexibility of double-layer board can be increased. Additionally, the low coefficient of thermal expansion and the low coefficient of water absorption of the characteristics of the first bonding layer 132 can further increase the bonding stability and reliability of the metal base material and the insulating layer.

That is, please refer to FIG. 1C again. A composite substrate is provided in some embodiments of the present disclosure, including a first metal base material, a first bonding layer 132 and a second metal base material. The first metal base material includes a first metal layer 112 and a first insulating layer 122, in which the first insulating layer 122 includes a first surface and a second surface opposite to the first surface, in which the first surface of the first insulating layer 122 faces down and is disposed on the first metal layer 112. A first bonding layer 132 is disposed on the second surface of the first insulating layer 122, in which a dielectric constant of the first bonding layer 132 is lower than 3, and a dissipation factor of the first bonding layer 132 is lower than 0.005. A second metal base material includes a second metal layer 114 and a second insulating layer 124, in which the second insulating layer 124 includes a third surface and a fourth surface opposite to the third surface, in which the third surface of the second insulating layer 124 faces down and is disposed on the first bonding layer 132, in which the second metal layer 114 is disposed on the fourth surface of the second insulating layer 124.

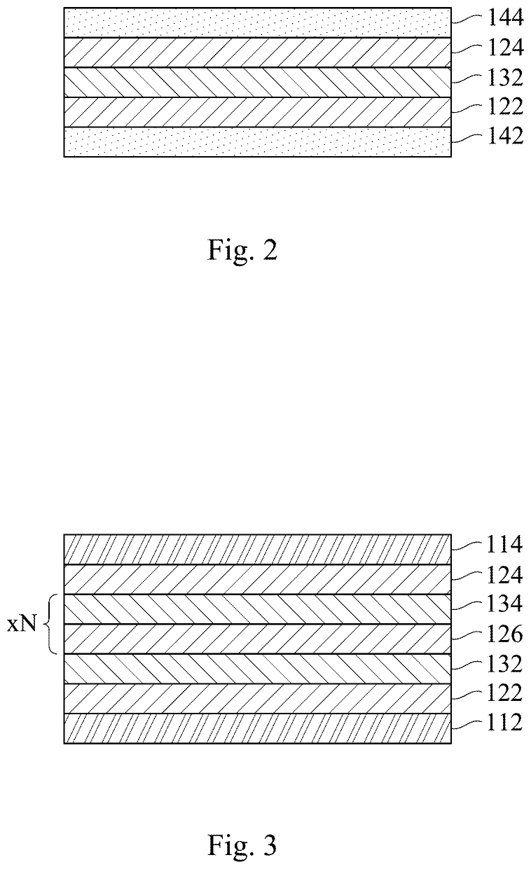

In some embodiments, a portion of metal layers or the whole metal layers are patterned metal layers, please refer to FIG. 2. FIG. 2 schematically illustrates a cross-sectional view of a composite substrate according to other embodiments of the present disclosure, such as the patterned first metal layer 142 and the patterned second metal layer 144. In some embodiments, a surface of the patterned metal layer includes a circuit structure.

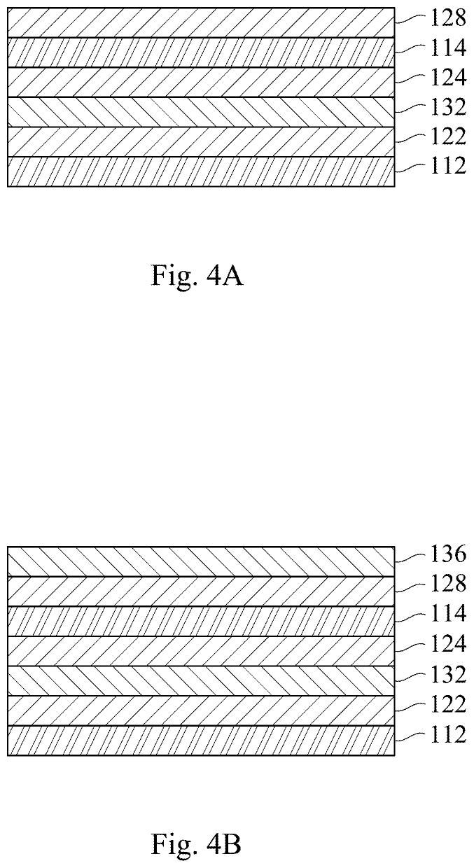

In some embodiments, some bonding structures of the bonding layer can be disposed between the first bonding layer 132 and the second metal base material. Accordingly, the thickness of the double-layer board can be flexibly increased depending on the requirements without the limitation of the thickness of the insulating layer. Please refer to FIG. 3. FIG. 3 schematically illustrates a cross-sectional view of a composite substrate according to other embodiments of the present disclosure, in which the bonding structure includes a plurality of third insulating layer 126 and a plurality of second bonding layer 134, and the third insulating layer 126 are laminated with the second bonding layer 134, and an undermost third insulating layer 126 is disposed on the first bonding layer 132, and an uppermost second bonding layer 134 is disposed beneath the second insulating layer 124.

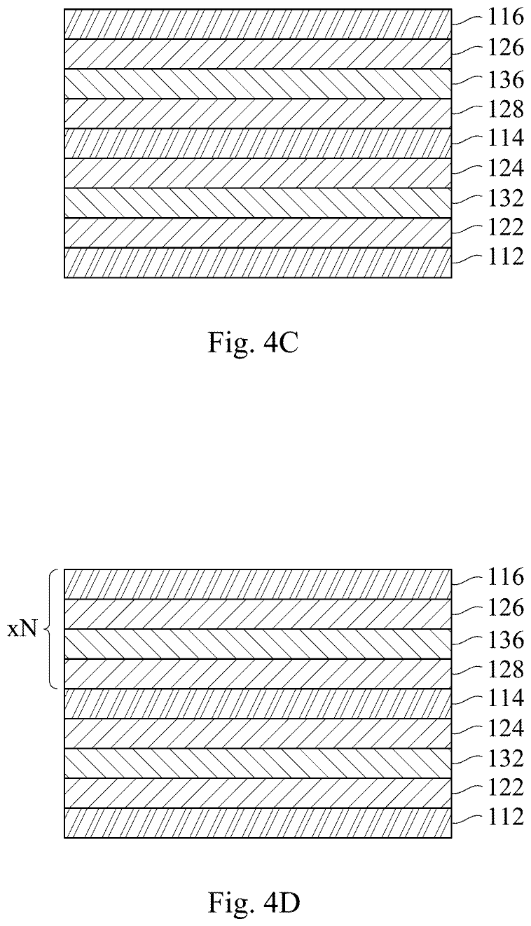

In some embodiments, multi-layer boards can be further formed in the manufacture basis of double-layer boards, such as FIGS. 4A to 4D, schematically illustrating cross-sectional views of a process flow of manufacturing a composite substrate according to other embodiments of the present disclosure. First, please refer to FIG. 4A. A fourth insulating layer 128 is disposed on the second metal layer 114 of FIG. 1C. Then, please refer to FIG. 4B to FIG. 4C. The third bonding layer 136 is disposed on the second metal base material, and then the third metal base layer is disposed on the third bonding layer 136, in which the third metal base layer includes a third metal layer 116 and a third insulating layer 126, and the third bonding layer 136 is adhered to the third insulating layer 126 and the fourth insulating layer 128 to obtain a three-layer board. The description of materials, parameters and the like in the process can be adjusted with reference to the aforementioned FIG. 1B to FIG. 1C according to the requirements, and will not be repeated herein. Furthermore, please refer to FIG. 4D. The composite substrate with different layers of the metal base materials can be obtained by repeating the manufacture process of FIGS. 4A to 4C according to the layer amount of the metal base materials required by the composite substrate. In some embodiments, the thickness of interlayers of the multi-layer board can be adjusted by cooperating with the bonding structure of abovementioned FIG. 3. The present disclosure of the multi-layer board manufacture process improves the adverse effects such as uneven adhesion caused by high temperature lamination, poor alignment or board shrinkage and deformation without affecting signal transmission and causing signal loss, and the types of the metal layers can be increased (such as the changes of the layer amount and the thickness of the interlayers).

In some embodiments, the materials of the multiple metal layers (such as the first metal layer 112, the second metal layer 114 and the third metal layer 116) can be the same or different. The materials of the multiple bonding layers (such as the first bonding layer 132, the second bonding layer 134 and the third bonding layer 136) can be the same or different.

In some embodiments, the composite substrate can further include one or a plurality of conductive holes penetrating the metal layers, the insulating layers and the bonding layers, and the materials filled in the conductive holes can be the same or similar to the materials of the metal layers.

Besides, the composite substrate of the present disclosure can be combined to form the thicker circuit board. For example, the insulating layer can include more than two layers of liquid crystal polymer, but not limited to this, and the layer amount, materials and the thickness of single layer can be adjusted according to different design requirements to cooperate with the disposition of the circuits on the surface of the composite substrate or wires supported.

The last to be emphasized is that the application of the bonding layers with low dielectric constant and low dielectric loss in some embodiments of the present disclosure let the producer adjust the spacing between the metal layers to meet the requirement of design and obtain the composite substrate with different thickness of interlayers without the adverse effects including uneven adhesion caused by high temperature, poor alignment or board shrinkage and deformation and the like, the signal transmission and the signal loss of the composite substrate will not be affected by the design of the bonding layers, and design flexibility and production yield can be increased.

Although the present disclosure has been described in considerable detail with reference to certain embodiments, other embodiments are possible. Therefore, the spirit and scope of the claim of the appended patent application should not be limited to the description of the embodiments contained herein.

What is claimed is:

1. A composite substrate, comprising:
a first metal base material, including a first metal layer and a first insulating layer, wherein the first insulating layer comprises a first surface and a second surface opposite to the first surface, wherein the first surface of the first insulating layer faces down and is disposed on the first metal layer;
a first bonding layer, disposed on the second surface of the first insulating layer, wherein a dielectric constant of the first bonding layer is lower than 3, and a dissipation factor of the first bonding layer is lower than 0.005; and
a second metal base material, comprising a second metal layer and a second insulating layer, wherein the second insulating layer comprises a third surface and a fourth surface opposite to the third surface, wherein the third surface of the second insulating layer faces down and is disposed on the first bonding layer, wherein the second metal layer is disposed on the fourth surface of the second insulating layer.

2. The composite substrate of claim 1, wherein a material of the first metal layer and the second metal layer comprises Cu, Al, Au, Ag, Sn, Pb, Sn—Pb alloy, Fe, Pd, Ni, Cr, Mo, W, Zn, Mn, Co, stainless steel, or a combination thereof.

3. The composite substrate of claim 1, wherein at least one of the first metal layer and the second metal layer is a patterned metal layer.

4. The composite substrate of claim 1, wherein a surface of the patterned metal layer includes a circuit structure.

5. The composite substrate of claim 1, wherein a material of the first insulating layer and the second insulating layer comprises Polyimide, Polyethylene Terephthalate, Teflon, Liquid Crystal Polymer, Polyethylene, Polypropylene, Polystyrene, Polyvinyl Chloride, Nylon, Acrylic, Acrylonitrile-Butadiene-Styrene, Phenolic Resins, Epoxy, Polyester, Silicone, Polyurethane, polyamide-imide, or a combination thereof.

6. The composite substrate of claim 1, wherein either the first insulating layer, the second insulating layer, or both are a modified insulating material.

7. The composite substrate of claim 6, wherein the modified insulating material comprises a modified polyimide, a soluble liquid crystal polymer, or a combination thereof.

8. The composite substrate of claim 7, wherein the soluble liquid crystal polymer comprises a functional group selected from the group consisting of amino group, carboxamido group, imido group, amidino group, aminocarbonylamino group, aminothiocarbonyl group, aminocarbonyloxy group, aminosulfonyl group, aminosulfonyloxy group, aminosulfonylamino group, carboxyl ester group, (carboxyl ester)amino group, alkoxycarbonyl)oxy group, alkoxycarbonyl group, hydroxyamino group, alkoxyamino group, cyanate group and isocyanato group.

9. The composite substrate of claim 1, wherein a coefficient of thermal expansion of the first bonding layer is lower than 50 μm/m/° C.

10. The composite substrate of claim 1, wherein a coefficient of water absorption of the first bonding layer is lower than 0.5% at a temperature of 25° C. within 24 hours.

11. The composite substrate of claim 1, wherein a material of the first bonding layer comprises polyester resin, epoxy resin, butyral phenolic resin, phenoxy resin, acrylic resin, polyurethane resin, silicone rubber resin, parylene resin, bismaleinide resin, polyimide resin, urethane resin, silicon dioxide resin, flueon resin, or a combination thereof.

12. The composite substrate of claim 1, further comprising a bonding structure is located between the first bonding layer and the second metal base material, and the bonding structure comprising a second bonding layer.

13. The composite substrate of claim 12, wherein the bonding structure further comprises a plurality of third insulating layers and a plurality of second bonding layers, wherein any one of the plurality of third insulating layers is laminated with any one of the plurality of second bonding layers, wherein an undermost third insulating layer of the plurality of third insulating layers is disposed on the first bonding layer, and an uppermost second bonding layer of the plurality of second bonding layers is disposed beneath the second insulating layer.

14. A method of manufacturing a composite substrate, comprising following steps:
providing a first metal base material, comprising a first metal layer and a first insulating layer, wherein the first insulating layer is disposed on the first metal layer;
providing a second metal base material, comprising a second metal layer and a second insulating layer, wherein the second insulating layer is disposed beneath the second metal layer;
providing a first bonding layer, wherein a dielectric constant of the first bonding layer is lower than 3, and a dissipation factor of the first bonding layer is lower than 0.005; and
disposing the first bonding layer between the first metal base material and the second metal base material to obtain a composite substrate, wherein the first bonding layer is adhered to the first insulating layer and the second insulating layer.

15. The method of claim 14, further comprising forming a bonding structure between the first bonding layer and the second metal base material, wherein the bonding structure comprises a second bonding layer.

16. The method of claim 15, wherein the bonding structure further comprises a plurality of third insulating layers and a plurality of second bonding layers, wherein any one of the plurality of third insulating layers is laminated with any one of the plurality of second bonding layers, wherein an undermost third insulating layer of the plurality of third insulating layers is disposed on the first bonding layer, and an uppermost second bonding layer of the plurality of second bonding layers is disposed beneath the second insulating layer.

17. The method of claim 14, wherein the step of disposing the first bonding layer between the first metal base material and the second metal base material comprises heating the first bonding layer at a temperature of lower than 280° C. to adhere the first bonding layer between the first metal base material and the second metal base material.

18. The method of claim 14, wherein the step of heating the first bonding layer at the temperature of lower than 280° C. comprises a first heating stage and a second heating stage.

19. The method of claim 18, wherein a temperature of the first heating stage is from 100° C. to 150° C.

20. The method of claim 18, wherein a temperature of the second heating stage is from 250° C. to 280° C.
